(19) United States
(12) Patent Application Publication
(10) Pub. No.: US 2022/0353998 A1
(43) Pub. Date: Nov. 3, 2022

(54) Roll-to-Roll Copper Foil Laminating Device

(71) Applicant: Xiamen University of Technology, Xiamen (CN)

(72) Inventors: An Xie, Xiamen (CN); Dongya Sun, Xiamen (CN); Liang Yang, Xiamen (CN); Yuechan Li, Xiamen (CN); Chunyan Cao, Xiamen (CN); Xiangjun Lu, Xiamen (CN)

(21) Appl. No.: 17/542,541

(22) Filed: Dec. 6, 2021

(30) Foreign Application Priority Data
Apr. 28, 2021 (CN) 202110470799.0

(51) Int. Cl. H05K 3/02; H05K 3/36

(52) U.S. Cl. CPC H05K 3/022; H05K 3/361; H05K 2203/068; H05K 2203/0235

(57) ABSTRACT

Provided is a roll-to-roll copper foil laminating device. The device comprises a dry film holder shaft, a copper foil holder shaft, and a dry film roll connected to the dry film holder shaft; an outer surface of the copper foil frame shaft is wound with a copper foil roll. Before the dry film roll contacts a diffuser roller, the dry film roll goes through an EPC correction structure and remain in a state of active bonding; the distance from the dry film roll to the diffuser roller is 1.5 times a distance from the copper foil roll to the diffuser roller; a rotation axis of the dry film holder shaft and a rotation axis of the copper foil holder shaft move synchronously with an outer spin column.

### CROSS REFERENCE OF RELATED APPLICATIONS

The present disclosure claims the benefit of Chinese Patent Application No. 202110470799.0 entitled “Roll-to-Roll Copper Foil Laminating Device,” filed on Apr. 28, 2021, in the China National Intellectual Property Administration, the entire content of which is incorporated herein in its entirety.

### TECHNICAL FIELD

The present disclosure relates to a flexible circuit board manufacturing equipment, in particular to a roll-to-roll copper foil laminating device.

### BACKGROUND

The flexible circuit board is a flexible printed circuit board made of polyimide or polyester film as the base material. It can be bent and folded freely and has high wiring density. It gradually replaces the PCB circuit board. Copper foil is generally used as a conductor during preparation. The surface of copper foil is relatively smooth and has good flexibility. It needs to be covered with a dry film on the surface to protect the copper foil. It is a polymer compound that can resist ultraviolet radiation. It is attached to the copper foil to protect it under irradiation.

Based on the above description, the inventor found that the existing copper foil laminating device mainly has the following shortcomings. For example, the traditional sheet laminator cannot fully bond the dry film and the copper foil under the continuous working state, and the copper foil and the copper foil The bonding accuracy of the dry film is low, resulting in poor post-line production yield, easy to break circuits between the lines, and low utilization of the dry film during film lamination, and poor dry film cutting at the edge of the copper foil board. Lead to phenomena such as unsightly and waste.

### SUMMARY

In order to solve the above technical problems, the present disclosure provides a roll-to-roll copper foil laminating device to solve the existing problems.

The present disclosure is achieved by the following disclosure.

A roll-to-roll copper foil laminating device is provided by the present disclosure. The roll-to-roll copper foil laminating device comprises a dry film holder shaft (81), a copper foil holder shaft (91), and a dry film roll (80) connected to the dry film holder shaft (81); an outer surface of the copper foil frame shaft (91) is wound with a copper foil roll (90); before the dry film roll (80) contacts a diffuser roller (40), the dry film roll (80) goes through an EPC correction structure (84) and remain in a state of active bonding; the distance from the dry film roll (80) to the diffuser roller (40) is 1.5 times a distance from the copper foil roll (90) to the diffuser roller (40); a rotation axis of the dry film holder shaft (81) and a rotation axis of the copper foil holder shaft (91) move synchronously with an outer spin column (500).

In some embodiments, the dry film roll (80) passes through a top of abending shaft (82) and a heating shaft (83) in sequence; a bottom of the dry film roll (80) and a bottom of the heating shaft (83) have an angle of 30°.

In some embodiments, the copper foil roll (90) passes through an upper part of the first transmission shaft (92) and the second transmission shaft in sequence; the bottom of (93) and the bottom of the diffuser roller (40) are movably attached together; the copper foil roll (90) passes through the upper part of the first transmission shaft (92) and the second transmission shaft (93); the angle between the time and the two is 45°.

In some embodiments, the diffuser roller (40) further comprises a repressing roller (30) connected to it in transmission; the left and right sides of the repressing roller (30) are both wrapped by the edge cutting structure (20).

In some embodiments, the left and right sides of the dry film holder shaft (81) and the copper foil holder shaft (91) are connected with external; the slinger (500), the four outer slings (500) provided with a total of four comprise an inner pressing bar (511), and the outer slinger (500) and the inner pressing bar (511) are both on the guide rail (522) is internally movable; the inner side of the four guide rails (522) comprises a dual-axis linkage frame (533), and the interior of the dual-axis linkage frame (533) is filled with liquid colloid, which has high fluidity.

In some embodiments, the upper and lower ends of the inner middle section of the biaxial linkage frame (533) respectively comprise a positive electrode guide plate (30a) and a negative electrode guide plate (30c), the positive electrode guide plate (30a) and the negative electrode guide plate (30c) comprise a flow guide ball (30b) between the positive electrode guide plate (30a) and the negative electrode guide plate (30c); the flow guide ball (30b) is filled with liquid glue inside the biaxial linkage frame (533) shape body activity fits.

In some embodiments, the left and right ends of the dry film roll (80) passing through the top of the EPC correcting structure (84) comprise displacement; the sensor (841) also comprises a digital signal transmitter (842) that is electrically connected to the displacement sensor (841), the digital signal transmitter (842) and the servo motor group (843) are connected together by electrical signals; the servo motor groups (843) at both ends share signals through the linkage line (840).

In some embodiments, the servo motor group (843) comprises a servo motor (433) connected to a digital signal transmitter (842)), the right side of the servo motor (433) comprises two correction arms (431), the inner sides of the upper and lower correction arms (431) are connected with a flexible suction plate (430), the correction arm (431); a drum arm (432) is connected to the outer side of the motor and is mechanically connected with the servo motor (433).

In some embodiments, the edge cutting structure (20) comprises a movable sliding frame (230), and the sliding frame (230) is connected to the inner three sides of the edge-trimming knife (220), the inside of the edge-trimming knife (220) comprises more than two edge-sealing clips (210), the edge-sealing clip (210); the inner side is glued with a whole row of beards and is the same length as the edge trimming knife (220).

The present disclosure is a roll-to-roll copper foil laminating device with reasonable design and strong functionality, and has the following advantages. The dry film frame shaft and the copper foil frame shaft are synchronized to the roll through the roll-to-roll transmission, so that the relationship between the two is always maintained. In the state of uniform motion and synchronization, the two can achieve perfect fit under the action of the diffuser roller and the recompression roller, improve the precision of the film, and optimize the overall yield of the line, and the EPC correction method is also adopted to monitor the movement and transmission status of the dry film at all times, and make timely adjustments in the event of deviation, so that the dry film can always remain on the same vertical plane as the copper foil without shifting, and improve the utilization of the dry film.

### BRIEF DESCRIPTION OF THE DRAWINGS

In order to explain the technical solutions of the embodiments of the present disclosure more clearly, the following will briefly introduce the drawings that need to be used in the embodiments. It should be understood that the following drawings only show certain embodiments of the present disclosure, and therefore do not It should be regarded as a limitation of the scope. For those of ordinary skill in the art, without creative work, other related drawings can be obtained based on these drawings.

FIG. 1 is a schematic diagram of a roll-to-roll copper foil laminating device according to embodiments of the present disclosure.

FIG. 2 is a schematic diagram of the dry film holder shaft and the copper holder shaft from right side view according to embodiments of the present disclosure.

FIG. 3 is a three-dimensional structural diagram of the inner center of the dual-axis linkage frame according to embodiments of the present disclosure.

FIG. 4 is a schematic diagram of the EPC correction structure from right side view according to embodiments of the present disclosure.

FIG. 5 is a schematic diagram of the structure of the servo motor group from the top view according to embodiments of the present disclosure.

FIG. 6 is a schematic diagram of the edge cutting structure from top view according to embodiments of the present disclosure.

Reference characters: edge cutting structure—20, recompression roller—30, diffuser roller—40, edge banding clip—210, edge trimming knife—220, sliding frame—230, positive guide plate—30a, Flow guide ball—30b, negative guide plate—30c, flexible suction plate—430, correction arm—431, drum arm—432, servo motor—433, outer sling—500, inner pressure strip—511, guide rail—522, double Axis linkage frame—533, dry film roll—80, dry film frame shaft—81, bending shaft—82, heating shaft—83, EPC correction structure—84, copper foil roll—90, copper foil frame shaft—91, No. A transmission shaft—92, a second transmission shaft—93, a displacement sensor—841, a digital signal transmitter—842, and a servo motor group—843.

### DETAILED DESCRIPTION OF THE EMBODIMENTS

In order to make it easy to understand the technical means, creative features, objectives and effects achieved by the present invention, the present invention will be further explained below in conjunction with specific implementations.

As shown in FIG. 1, the present invention provides a roll-to-roll copper foil laminating device. The device includes a dry film holder shaft 81, a copper foil holder shaft 91, and a dry film roll 80 connected to the dry film holder shaft 81. A copper foil roll 90 is wound on the outer surface of the copper foil frame shaft 91. The dry film roll 80 needs to pass through the EPC correcting structure 84 immediately before contacting with the diffuser roller 40 and is kept in a movably attached state at all times. The distance from the dry film roll 80 to the diffuser roller 40 is 1.5 times the distance from the copper foil roll 90 to the diffuser roller 40. The rotation axis of the dry film carrier shaft 81 and the rotation axis of the copper foil carrier shaft 91 both move synchronously with the outer sling 500. The dry film roll 80 passes through the top of the bending shaft 82, the bottom of the heating shaft 83, and the top of the EPC correction structure 84 in sequence, and is movably attached to the bottom of the diffuser roller 40. The angle between the two ends of the dry film roll 80 and the bottom of the heating shaft 83 is both 30°. The dry film roll 80 can be increased by a certain tension through the bending shaft 82. It is not easy to produce wrinkles when conveying and pressing. After the heating shaft 83 changes its internal molecular motion state, the internal molecules are more active, and it is easier to bond with the molecules of the copper foil, and the bonding degree with the copper foil is improved. The included angle of 30° can make the dry film fully contact the heating shaft 83, so that the dry film is heated to an optimal point, and it is not easy to be moved after being attached. The transmission distance of the dry film roll 80 is always about 1.5 times longer than that of the copper foil roll 90, so that the dry film is always in front of the copper foil to prevent part of the copper foil from leaving the warehouse without the effect of lamination. The dry film roll 80 is in contact with the EPC before the material is discharged, and can perform a deviation correction action at the beginning of operation, so as to prevent the phenomenon of deflection at the beginning and cause the waste of raw materials.

As shown in FIG. 1, the copper foil roll 90 sequentially passes through the top of the first transmission shaft 92 and the bottom of the second transmission shaft 93 and is movably attached to the bottom of the diffuser roller 40. When the copper foil roll 90 passes above the first transmission shaft 92 and the second transmission shaft 93, the included angle with both is 45°. The diffuser roller 40 also includes a recompression roller 30 connected to it in transmission. The left and right sides of the repressing roller 30 are both wrapped by the edge cutting structure 20. After being led out, the copper foil roll 90 needs to be kept tight under the tension of the first transmission shaft 92 and the second transmission shaft 93 without cracking. Moreover, the tension of the first transmission shaft 92 and the second transmission shaft 93 are the same, so that the tension existing in the copper foil is relatively stable. The diffuser roller 40 has an expansion valve inside, and the diffuser roller 40 is made of a flexible material, which can expand the roller body to squeeze out the air existing between the dry film and the copper foil, and improve the bonding rate of the two. There is a wedge-shaped notch on the right side of the repressing roller 30. After a model plate is pressed, the cutting device at the rear is reset at a certain interval to ensure the smoothness of the overall automation. When the angle between the copper foil roll 90 and the upper part of the first transmission shaft 92 and the second transmission shaft 93 is 45°, the copper foil can be tightly stretched, and the surface will not be torn, so that the internal tension can reach the best value. The lamination film fits tighter.

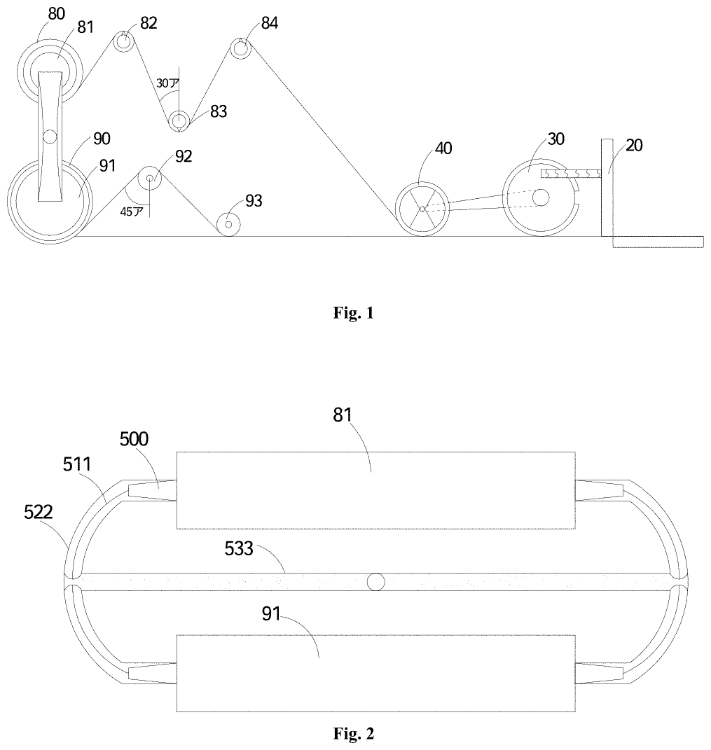

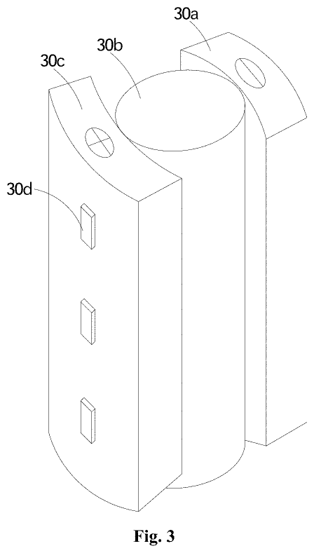

As shown in FIGS. 2 and 3, the left and right sides of the dry film holder shaft 81 and the copper foil holder shaft 91 are connected with outer slingers 500. The four outer swinging poles 500 provided in total include an inner pressing bar 511. Both the outer sling 500 and the inner pressing bar 511 move in the guide rail 522. The inner side of the four guide rails 522 includes a dual-axis linkage frame 533. The inside of the biaxial linkage frame 533 is filled with liquid gel, which has high fluidity. The upper and lower ends of the inner middle section of the biaxial linkage frame 533 respectively include a positive electrode guide plate 30a and a negative electrode guide plate 30c. The positive electrode guide plate 30a and the negative electrode guide plate 30c include a flow guide ball 30b in the middle. The flow guide ball 30b is movably attached to the liquid gel filled inside the dual-axis linkage frame 533. When the dry film frame shaft 81 and the copper foil frame shaft 91 rotate, the outer spin column 500 will be pushed out, allowing it to The inner pressing bar 511 pushes out the liquid squeezed into the biaxial linkage frame 533, so that the liquid at both ends can fix the flow guide ball 30b so as to keep it between the positive electrode guide plate 30a and the negative electrode guide plate 30c. At this time, a closed loop is formed as a whole. When one of the film frame shaft 81 and the copper foil frame shaft 91 has different pole rotation speeds, the position of the flow guide ball 30b will be changed, so that the positive electrode guide plate 30a and the negative electrode guide plate 30c cannot be connected, and the entire device is stopped when the power is cut off. In this way, the film holder shaft 81 and the copper foil holder shaft 91 can be in a roll-to-roll synchronization state during operation, so that the film lamination accuracy can be guaranteed.

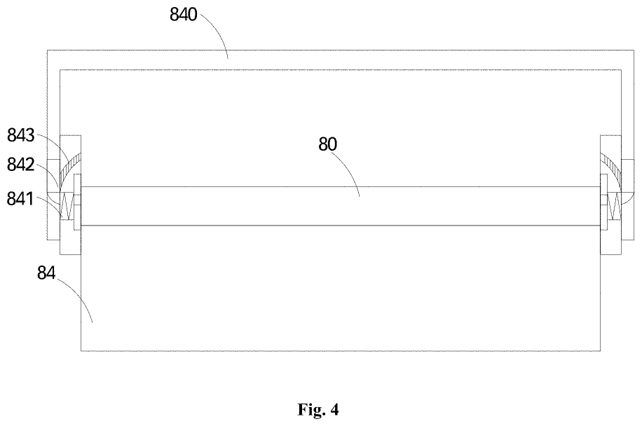

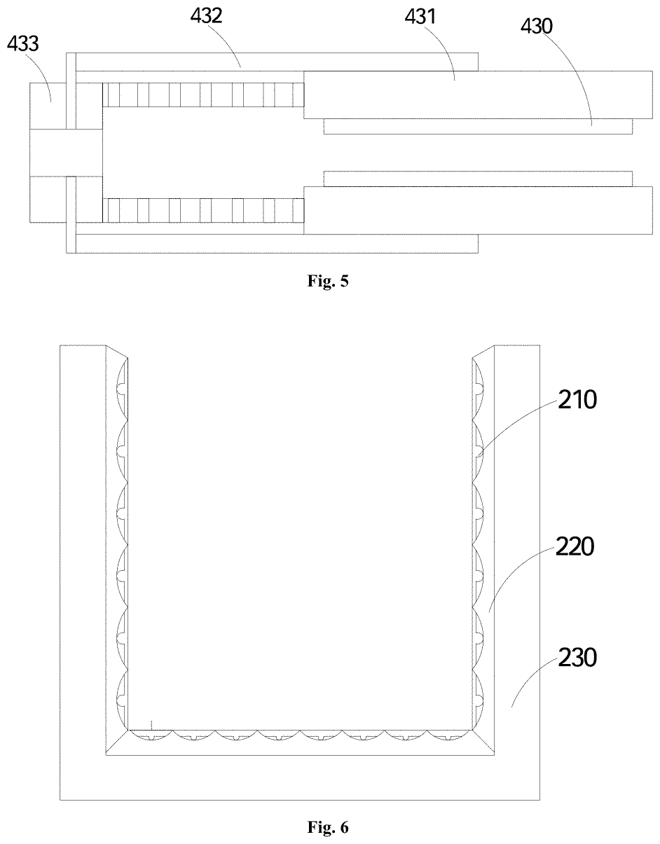

As shown in FIGS. 4 to 5, the left and right ends of the dry film roll 80 through which the top of the EPC correcting structure 84 passes through each include a displacement sensor 841, and a digital signal electrically connected to the displacement sensor 841. Transmitter 842. The digital signal transmitter 842 and the servo motor unit 843 are connected together by electrical signals. The servo maneuver groups 843 at the two ends share signals via the linkage line 840. The servo motor group 843 includes a servo motor 433 connected to a digital signal transmitter 842. The right side of the servo motor 433 includes two correction arms 431, the inner sides of the upper and lower correction arms 431 are connected with a flexible suction plate 430, and the outer side of the correction arm 431 is connected with a drum arm 432 and is connected to the servo motor 433. Mechanically connected together, adopting a new detection standard, the dry film needs to pass through the displacement sensor 841 before being transferred to the laminated film. If the position of the dry film deviates at this time, it will cause pressure on the column head of the displacement sensor 841, causing the deviation to generate a micro current and output it to the digital signal transmitter 842. The digital signal transmitter 842 imports it into the servo motor 433, so that the upper and lower servo motors 433 clamp the dry film by the drum arm 432, and then move it to the end where no current is generated through the correction arm 431, and automatically adjust the dry film. The direction of movement can prevent deviation, improve the accuracy of the bonding, so that the dry film is always perfectly bonded to the copper foil, and reduce the material loss caused by the offset direction.

As shown in FIG. 6, the edge cutting structure 20 includes a movable sliding frame 230, and the three inner sides of the sliding frame 230 are connected with edge trimming blades 220. The edge trimming knife 220 includes more than two edge sealing clips 210 inside. The inner side of the edge-sealing clip 210 is bonded with a whole row of hairs and is the same length as the edge trimmer 220. The edge-sealing clips 210 are tightly arranged without leaving gaps, which can ensure that each side can be tightly sealed during edge-sealing and prevent the phenomenon of falling off. The edge trimming knife 220 is three-directional, which can cut off the excess part of the dry film when the dry film is offset. The reciprocating time of the edge trimming knife 220 on the sliding frame 230 is exactly the same as the edge sealing time of the edge sealing clip 210. It is equal to the transition time of the wedge-shaped port on the recompression roller 30. The edge-sealing clip 210 quickly slides and squeezes the edge after cutting. The sealing speed is faster and there is no wrinkle due to the relatively flat contact surface. The edge-sealing clip 210 has roots in the middle when it comes into contact with the dry film. For buffering, the fibrous roots are softer flocks to prevent scratching the surface of the dry film and avoid affecting the later development and etching.

The above are only the preferred embodiments of the present disclosure and are not used to limit the present disclosure. For those skilled in the art, the present disclosure can have various modifications and changes. Any modification, equivalent replacement, improvement, etc. made within the spirit and principle of the present disclosure shall be comprised in the protection scope of the present disclosure.

What is claimed is:

1. A roll-to-roll copper foil laminating device, comprising:
a dry film holder shaft (81),
a copper foil holder shaft (91), and
a dry film roll (80) connected to the dry film holder shaft (81);
an outer surface of the copper foil frame shaft (91) is wound with a copper foil roll (90);
before the dry film roll (80) contacts a diffuser roller (40), the dry film roll (80) goes through an EPC correction structure (84) and remain in a state of active bonding; the distance from the dry film roll (80) to the diffuser roller (40) is 1.5 times a distance from the copper foil roll (90) to the diffuser roller (40); a rotation axis of the dry film holder shaft (81) and a rotation axis of the copper foil holder shaft (91) move synchronously with an outer spin column (500).

2. The device according to claim 1, wherein the dry film roll (80) passes through a top of abending shaft (82) and a heating shaft (83) in sequence; a bottom of the dry film roll (80) and a bottom of the heating shaft (83) have an angle of 30°.

3. The device according to claim 1, wherein the copper foil roll (90) passes through an upper part of the first transmission shaft (92) and the second transmission shaft in sequence; the bottom of (93) and the bottom of the diffuser roller (40) are movably attached together; the copper foil roll (90) passes through the upper part of the first transmission shaft (92) and the second transmission shaft (93); the angle between the time and the two is 45°.

4. The device according to claim 2, wherein the diffuser roller (40) further comprises a repressing roller (30) connected to it in transmission; the left and right sides of the repressing roller (30) are both wrapped by the edge cutting structure (20).

5. The device according to claim 1, wherein the left and right sides of the dry film holder shaft (81) and the copper foil holder shaft (91) are connected with external; the slinger (500), the four outer slings (500) provided with a total of four comprise an inner pressing bar (511), and the outer slinger (500) and the inner pressing bar (511) are both on the guide rail (522) is internally movable; the inner side of the four guide rails (522) comprises a dual-axis linkage frame (533), and the interior of the dual-axis linkage frame (533) is filled with liquid colloid, which has high fluidity.

6. The device according to claim 5, wherein the upper and lower ends of the inner middle section of the biaxial linkage frame (533) respectively comprise a positive electrode guide plate (30a) and a negative electrode guide plate (30c), the positive electrode guide plate (30a) and the negative electrode guide plate (30c) comprise a flow guide ball (30b) between the positive electrode guide plate (30a) and the negative electrode guide plate (30c); the flow guide ball (30b) is filled with liquid glue inside the biaxial linkage frame (533) shape body activity fits.

7. The device according to claim 2, wherein the left and right ends of the dry film roll (80) passing through the top of the EPC correcting structure (84) comprise displacement; the sensor (841) also comprises a digital signal transmitter (842) that is electrically connected to the displacement sensor (841), the digital signal transmitter (842) and the servo motor group (843) are connected together by electrical signals; the servo motor groups (843) at both ends share signals through the linkage line (840).

8. The device according to claim 7, wherein the servo motor group (843) comprises a servo motor (433) connected to a digital signal transmitter (842)), the right side of the servo motor (433) comprises two correction arms (431), the inner sides of the upper and lower correction arms (431) are connected with a flexible suction plate (430), the correction arm (431); a drum arm (432) is connected to the outer side of the motor and is mechanically connected with the servo motor (433).

9. The device according to claim 4, wherein the edge cutting structure (20) comprises a movable sliding frame (230), and the sliding frame (230) is connected to the inner three sides of the edge-trimming knife (220), the inside of the edge-trimming knife (220) comprises more than two edge-sealing clips (210), the edge-sealing clip (210); the inner side is glued with a whole row of beards and is the same length as the edge trimming knife (220).
